(19) United States
(12) Patent Application Publication
(10) Pub. No.: US 2026/0341632 A1
(43) Pub. Date: Oct. 29, 2026

(54) TEM SAMPLE EXTRACTION FROM FULL WAFERS

(71) Applicant: Carl Zeiss SMT GmbH, Oberkochen (DE)

(72) Inventors: Sascha MUELLER, Koenigsbronn (DE); Joerg WISSLER, Bad Nauheim (DE)

(21) Appl. No.: 19/654,418

(22) Filed: Apr. 21, 2026

(30) Foreign Application Priority Data
Apr. 25, 2025 (DE) 10 2025 115 932.7

(51) Int. Cl. H01J 37/305

(52) U.S. Cl. CPC H01J 37/3053; H01J 2237/31745; H01J 2237/31749

(57) ABSTRACT

A method of operating the dual beam device extracts samples, such as tiny samples, for use as TEM lamellas from semiconductor wafers. With the method and a dual beam device configured for executing the method, TEM lamellas can be extracted from wafers without the need to break wafers into pieces.

### CROSS-REFERENCE TO RELATED APPLICATION

This application claims benefit under 35 U.S.C. § 119 to German Application No. 10 2025 115 932.7, filed Apr. 25, 2025. The entire disclosure of this application is incorporated by reference herein.

### FIELD

The present disclosure relates to a dual-beam device and a method of operating the dual beam device, which can be configured to extract relatively small samples for use as TEM lamellas from semiconductor wafers without breaking the wafers into pieces.

### BACKGROUND

Semiconductor structures are amongst the finest man-made structures. Semiconductor manufacturing generally involves relatively precise manipulation, e.g., lithography or etching, of materials such as silicon or oxide at relatively fine scales in the range of nm. A wafer made of a thin slice of silicon can serve as the substrate for microelectronic devices containing semiconductor structures built in and upon the wafer. The semiconductor structures are constructed layer by layer using repeated processing steps that involve repeated chemical, mechanical, thermal and optical processes. Dimensions, shapes and placements of the semiconductor structures and patterns are generally subject to several influences. Many involved process steps such as the lithography exposure, etching or implantation can have an impact on the properties of the elements of the integrated circuits. Therefore, fabricated semiconductor structures can suffer from rare and different imperfections. Devices for quantitative metrology, defect-detection or defect review look for these imperfections.

The semiconductor structures are manufactured from a sequence of layers parallel to a substrate. During fabrication, semiconductor wafers can run through about 1000 process steps or more. Within the semiconductor wafer, about 100 and more parallel layers can be formed, comprising transistor layers, the layers of the middle of the line, and the interconnect layers and, in areas of memory, a plurality of 3D arrays of memory cells. For example, in a logic type wafer sample, the critical structures within the critical layers are typically buried below dozens to hundreds of further layers, for example interconnection or metal layers or isolating layers. Within these layers, metal lines run parallel and metal vias run perpendicular to the layers. The critical structures in the lower, critical layers can comprise features of the critical dimension, which are relevant for a performance of a logic chip. For example, the minimum feature size or critical dimension is below 10 nm, for example 7 nm or 5 nm, and is approaching feature sizes below 3 nm or even less in near future. With FinFets and variations thereof, the complexity and dimensions of the critical layers is growing into the 3^{rd} dimension and of complex 3D-structures are built within. For example, within FinFets according to gate-all-around technology, tiny stacks of wires or sheets are stacked on top of each other. For example, stacked FinFets comprise several gate layers. It is therefore desirable to measure the shape, dimensions and orientation of the three-dimensional (3D) features and patterns within the deeply buried critical layers.

A common way to investigate the performance of a semiconductor fabrication process uses transmission electron microscopy (TEM). Since electrons generally transmit only very thin samples with thicknesses below 1 μm, below 500 nm or even less, thin samples, so called lamella are extracted from semiconductor wafers. According to certain known methods, the process of lamella extraction involves breaking a wafer into pieces and extracting and preparing a thin lamella from those broken wafer samples. The lamella extraction and preparation is performed with dual beam devices. Those devices comprise at least two charged particle beam columns, for example at least one focused ion beam column and for example a scanning electron microscope. The at least two charged particle beam columns are arranged at an angle to each other of for example 90° or less, for example 60°, 54° or even less. During the lamella extraction and preparation, the sample is tilted into several orientations, and the lamella is separated from the sample. The tilt of the sample and the geometrical constraints generally do not allow a sample extraction directly from a wafer.

Another technique to generate data from semiconductor wafers directly is the so-called slice-and image-method obtained by a dual beam device. The slice and image method for wafer inspection is for example described in WO 2021/180600 A1. According to this method, a 3D volume image of an inspection volume within a wafer is obtained by slicing and imaging a plurality of cross-section surfaces into the wafer. For a relatively precise measurement, a large number N of cross-section surfaces in the inspection volume is generated, with the number N exceeding 100 or even more image slices. However, the slice-and image method can be relatively time consuming.

US 2004/0089821 A1 discloses a sample fabricating method of irradiating a sample with a focused ion beam at an incident angle less than 90 degrees with respect to the surface of the sample. The method comprises eliminating the peripheral area of a micro sample as a target, turning a specimen stage around a line segment perpendicular to the sample surface as a turn axis, irradiating the sample with the focused ion beam while the incident angle on the sample surface is fixed, and separating the micro sample or preparing the micro sample to be separated. A sample fabricating apparatus for forming a sample section in a sample held on a specimen stage by scanning and deflecting an ion beam, wherein an angle between an optical axis of the ion beam and the surface of the specimen stage is fixed and formation of a sample section is controlled by turning the specimen stage.

### SUMMARY

The disclosure seeks to provide an improved inspection method applicable, for example, to full wafers.

The disclosure seeks to provide a method of investigating deeply buried critical layers within wafers without breaking the wafer into pieces.

In an aspect, the disclosure provides a method of extracting a sample, such as a tiny sample, from a complete or full wafer is given, without breaking the wafer into pieces. The sample corresponds to a relatively small wafer volume inside the wafer. The method comprises arranging an inspection site on a surface of the wafer at an intersection point of a dual beam device, comprising an imaging charged particle beam and a focused ion beam. The focused ion beam is arranged under an angle GF to the surface of the wafer with an angle GF between 20°<GF<60°. The method comprises performing a sequence of J milling operations for forming a number of J cuts into the surface of the wafer, whereby the number J of cuts is at least three. The method further comprises rotating the wafer by a wafer rotation angle RA by a wafer stage around an axis normal to the wafer surface. In an example, rotating the wafer is performed between at least two milling operations selected from the sequence of J milling operations. The method further comprises attaching a micro-manipulator to the surface of the wafer volume before executing a final milling operation selected from the sequence of J milling operations. The sequence of J milling operations comprises a final milling operation with the focused ion beam for forming a final cut into the wafer surface, thereby disconnecting a wafer volume connected to the micro-manipulator from the wafer.

In an example, at least one milling operation selected from the sequence of J milling operations comprises scanning deflecting the focused ion beam with scanning deflector in a first scanning direction perpendicular to a normal to a surface of the wafer and an optical axis of the focused ion beam column. In an example, at least one milling operation selected from the sequence of J milling operations comprises scanning deflecting the focused ion beam in a second scanning direction in a plane comprising a normal to a surface of the wafer and an optical axis of the focused ion beam. In an example, at least one milling operation selected from the sequence of J milling operations comprises scanning deflecting the focused ion beam in a third scanning direction according to a scan rotation, thereby forming a cut at an angle ACA with GF<ACA<90° to a wafer surface. In an example, the scan rotation is adjusted such that the angle ACA deviates from a normal to the wafer surface by more than 5°, for example 10°, for example 15°. The sequence of J milling operations can comprise at least one milling operation configured for forming an undercut below the wafer volume, such that the wafer volume corresponding to the sample to be extracted is between the undercut and the wafer surface. For example, the undercut below the wafer volume is formed at an angle GF to the wafer surface. In another example, the undercut below the wafer volume to be extracted is formed at an angle ACA with GF<ACA<90° to the wafer surface, for example with an angle ACA with GF<ACA<85° or even less, for example GF<ACA<80°.

In an example, the method comprises forming a joint cutting intersection by at least two milling operations selected from the sequence of J milling operations. For example, the cutting intersection is formed by at least one milling operation configured for forming an undercut below the wafer volume and at least one further milling operation selected from the sequence of J milling operations. For example, at least one step of rotating the wafer by a wafer rotation angle RA is executed between the two milling operations for forming the joint cutting intersection. The wafer rotation angle RA can be selected according to an angle selected from RA=90° or RA=180°, but other wafer rotation angles are possible as well, for example wafer rotation angle RA=120°. In an example, the method further comprises displacing the wafer by wafer stage in a direction perpendicular to at least one of the J>=3 cuts.

For example, the joint cutting intersection is formed at a depth dz. During each milling operation selected from the sequence of J milling operations, a milling operation is controlled according to the depth dz below the wafer surface. For example, a milling time at each scanning position is controlled or a cycle of scanning operations is controlled until the depth dz below the wafer surface is reached by a milling operation. The depth dz can be about 3 μm or more, for example dz=5 μm, for example dz=10 μm.

In an example, the sample is formed with a shape selected from a group of shapes including a tetrahedron, a pyramid, an elongated shape with triangular cross-section, a shape of a disk with parallel sidewalls and rectangular cross-section, and a shape of a disk with parallel sidewalls and triangular cross-section.

In an example, the method comprises extracting the sample by the micro-manipulator from the wafer. In an example, the method comprises further milling operations with the focused ion beam configured for shaping the sample or polishing at least one face of the sample. Such operations can include a backside thinning, a frontside thinning, a cutting of samples, such as tiny samples, into samples with parallel sidewalls, and a polishing of sidewalls by ion-beam polishing under a glancing angle. The method may further comprise attaching the sample to a TEM lamella sample holder.

According to an aspect, the disclosure provides a wafer inspection system configured for extracting TEM lamellas from full wafers. The wafer inspection system comprises a dual beam system, comprising a focused ion beam column and a charged particle beam (CPB) imaging system arranged at an angle with respect to each other. The wafer inspection system comprises a wafer stage with a wafer support table for holding a wafer during use of the wafer inspection system. The optical axis of the focused ion beam column is arranged at an angle 20°<=GF<=60° to the surface of the wafer support table. The wafer inspection system comprises a movable micro-manipulator and a gas injection system for providing a process gas. The operation control unit of the wafer inspection system comprises a a memory for storing software instructions. The wafer inspection system is configured for performing a sequence of J milling operations for forming at least J>=3 cuts into a surface of a wafer, and for rotating, between at least two milling operations selected from the sequence of J milling operations, the wafer by a wafer rotation angle RA by a wafer stage around an axis normal to the wafer surface. For example, during execution of the software instructions, the wafer inspection system is configured for performing method steps described above.

The method and the wafer inspection system can be described for the example of semiconductor wafers comprising for example logic structures or processors, for example comprising a stack of interconnection layers covering the critical layers with the features of interest of a wafer inspection task. The method and the wafer inspection system, however, are not limited to wafer inspection but can applied to other types of disk-like objects as well, such as lithography masks. With the method and the wafer inspection system, it is possible to extract small volumes from a full wafer, for example wafer volumes comprising critical layers with the features of interest. Such wafer volumes can be extracted as samples, such as tiny samples, and can be further processed to form TEM lamellas from the samples. The TEM lamellas can be further investigated by TEM or STEM imaging techniques as known in the art.

The disclosure described by examples and embodiments is not limited to the embodiments and examples but can be implemented by those skilled in the art by various combinations or modifications thereof.

### BRIEF DESCRIPTION OF THE DRAWINGS

The present disclosure will be even more fully understood with reference to the following drawings:

FIG. 1 shows an illustration of a wafer inspection or metrology system with a dual beam device;

FIG. 2 is an illustration of the slice-and image method of a volume inspection in a wafer. ;

FIGS. 3A-3B illustrate a milling operation with a first scanning direction of a FIB;

FIGS. 4A-4D illustrate a milling operation with a second scanning direction of a FIB;

FIGS. 5A-5B illustrate a milling operation with a rotation of the scanning direction of a FIB;

FIGS. 6A-6F illustrate a first example of a sample extraction method;

FIGS. 7A-7D illustrate a second example of a sample extraction method;

FIGS. 8A-8E illustrate a third example of a sample extraction method;

FIGS. 9A-9B illustrate a fourth example of a sample extraction method;

FIGS. 10A-10B illustrate a fifth example of a sample extraction method;

FIGS. 11A-11C illustrate a sixth example of a sample extraction method;

FIGS. 12A-12D illustrate a seventh example of a sample extraction method;

FIG. 13 illustrates a sample extraction method; and

FIG. 14 illustrates a dual beam device configured for a sample extraction method.

### DETAILED DESCRIPTION

Throughout the figures and the description, same reference numbers are used to describe same features or components, and reference is also made to the first description of a feature or component. Throughout the disclosure, a system coordinate system is used with plane formed by x-and y-axis parallel to a wafer surface and a z-axis perpendicular to the wafer surface. Throughout the disclosure, a wafer coordinate system is described by coordinates wx, wy.

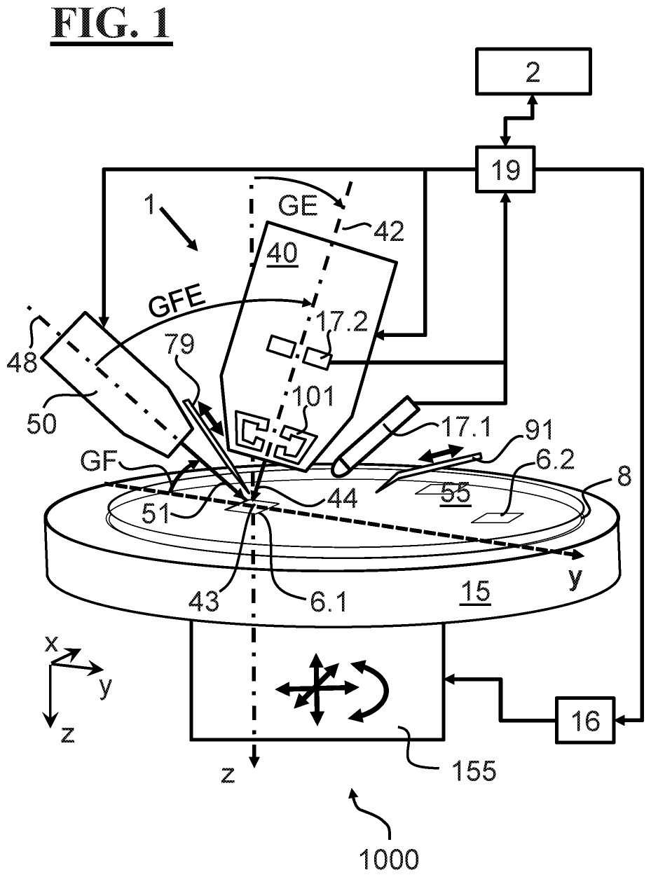

According to a first embodiment, a wafer inspection system is provided which is configured for extraction of a sample, such as a tiny sample, from a full wafer without breaking the wafer into pieces. A tiny sample has a small extension below 5 μm, below 3 μm or even less, for example below 1 μm in at least one dimension. In an example, the dual beam device is further configured to prepare a TEM lamella from the sample. An example of a wafer inspection system according to the first embodiment is illustrated in FIG. 1. The wafer inspection system 1000 is configured for a slice and imaging method under a wedge cut geometry with a dual beam device 1. For a wafer 8, several inspection sites, comprising inspection sites 6.1 and 6.2, are defined in a location map or inspection list generated from an inspection tool or from design information. The wafer 8 is placed on a wafer support table 15. The wafer support table 15 is mounted on a stage 155 with actuators and position control. Actuators and mechanisms for precision control for a wafer stage such as Laser interferometers are known in the art. A control unit 16 is configured to control the wafer stage 155 and to adjust an inspection site 6.1 of the wafer 8 at the intersection point 43 of the dual-beam device 1. The dual beam device 1 comprises a FIB column 50 with a FIB optical axis 48 and a charged particle beam (CPB) imaging system 40 with optical axis 42. At the intersection point 43 of both optical axes of FIB and CPB imaging system, the wafer surface 55 is arranged. The FIB axis 48 forms a slanted angle GF to the surface of the wafer support table 15. FIB axis 48 and CPB imaging system axis 42 include an angle GFE, and the CPB imaging system axis forms an angle GE with the normal to the surface of the wafer support table 15. In the coordinate system of FIG. 1, the normal to the surface of the wafer support table 15 is given by the z-axis. The focused ion beam (FIB) 51 is generated by the FIB-column 50 and is impinging under angle GF on the surface 55 of the wafer 8. Surface 55 of the wafer 8 is parallel to the surface of the wafer support table 15. Slanted cross-section surfaces are milled into the wafer by ion beam milling at the inspection site 6.1 under approximately the slant angle GF. In the example of FIG. 1, the slant angle GF is approximately 30°, but other angles GF, for example between GF=20° and GF=60°are possible as well. The actual slant angle of the slanted cross-section surface can deviate from the slant angle GF by up to 1° to 4° due to the beam divergency of the focused ion beam, for example a Gallium-Ion beam. With the charged particle beam imaging system 40, inclined under angle GE to the wafer normal, images of the wafer surface 55 or the milled surfaces are acquired. In the example of FIG. 1, the angle GE is about 15°. However, other arrangements are possible as well, for example with GE=GF, such that the CPB imaging system axis 42 is perpendicular to the FIB axis 48, or GE=0°, such that the CPB imaging system axis 42 is perpendicular to the wafer surface 55.

During imaging, a beam of charged particles 44 is scanned by a scanning unit of the charged particle beam imaging system 40 along a scan path over a surface of the wafer at inspection site 6.1, and secondary particles as well as scattered particles are generated. Particle detector 17.1 collects at least some of the secondary particles and scattered particles and communicates the particle count with a control unit 19. Other detectors for other of interaction products may be present as well, for example an in-lens detector 17.2 for collecting backscattered electrons (BSE). The charged particle beam imaging system 40 can comprise a magnetic lens 101 with an axial gap. With the axial gap between the pole shoes of such a lens, the magnetic field is constrained in an area well above the wafer surface such that the wafer surface 55 is almost free of magnetic fields. In absence of disturbing magnetic fields at the wafer surface 55 it is possible to perform a milling operation by FIB 51 parallel to an image acquisition with the charged particle beam imaging system 40. With parallel monitoring through the charged particle beam imaging system 40, a precision of a milling operation can be improved.

The dual beam device 1 further comprises a gas injection system GIS 91, which can be extracted or inserted close to the intersection point 43. Thereby, during use, dedicated process gases can be provided for charged particle beam assisted etching or deposition or chemically assisted milling into a wafer surface 55 at the inspection site 6.1. For example, process gases can be provided which bond to milling products to prevent redeposition of milling products onto the wafer surface 55. For example, Tungsten Hexacarbonyl can be provided for forming Tungsten layers on the wafer surface 55. The gas injection system GIS 91 comprises a gas nozzle and a valve, connected to at least one reservoir of precursor gases. Examples of precursor gases comprise at least one of Ammonia, Ammonium Hydroxide, Ammonium Carbamate, Bromine, Chlorine, Hydrazine, Hydrogen Peroxide, Hadacidin, Iodine, di-iodo-ethane, Isopropanol, Methy Difluoroacetate, Nitroethane, Nitroethanol, Nitrogen, Nitrogen Tetroxide, Nitrogen Trifluoride, Nitromethane, Nitropropane, Nitrobutane, Oxygen, Ozone, PMCPS, Tungsten Hexacarbonyl, Water, or Xenon Difluoride. Other gases are, however, are possible as well, for example methoxy acetylchloride, methyl acetate, methyl nitroacetate, ethyl acetate, ethyl nitroacetate, propyl acetate, propyl nitroacetate, nitro ethyl acetate, methyl methoxyacetate, and methoxy acetylchloride, Acetic acid or thiolacetic acid, Hexafluoroacetylacetone, silazane, trifluoroacetamide, dicobalt octacarbonyl, molybdenum hexacarbonyl, Formic acid, Formamide, Acetamide, N-methylacetamide, Propionyl Chloride, Propanioc acid, N, N-dimethylethanamide, Nitro acetic acid, Butyric acid, Lactic acid and combinations thereof.

The dual beam device 1 further comprises a micro manipulator 79, which is movable and can be controlled by control unit 19 to be brought into contact with the sample. Such micro-manipulators are known in the art. During use, a sample can be attached to the micro manipulator 79 and extracted from the wafer 8. The attaching is for example achieved by deposition of a chemical bond between the micro manipulator 79 and the sample by charged particle beam assisted deposition of components of a precursor gas provided by GIS 91. Thereby, a positive substance joint is formed. After use, the positive substance joint can be disconnected for example by ion beam milling.

Control unit 19 is in control of the charged particle beam imaging column 40 and of FIB column 50 and connected to the stage control unit 16 to control the position of the wafer 8 mounted on the wafer support table 15 via the wafer stage 155. Control unit 19 is in control of the GIS 91 and the micro manipulator 79. Control unit 19 communicates with operation control unit 2, which triggers placement and alignment for example of inspection site 6.1 of the wafer 8 at the intersection point 43 via wafer stage movement.

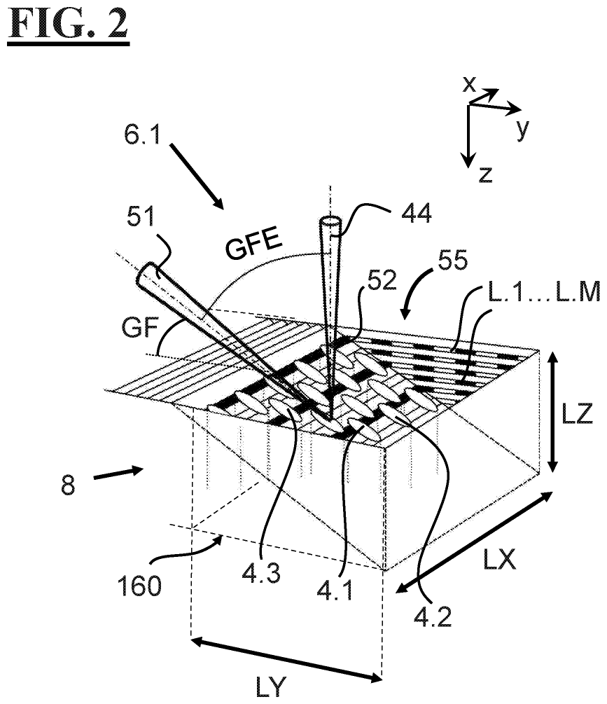

FIG. 2 illustrates an example of a cross-section formed within an inspection volume of a wafer 8. A cross-section surface 52 is milled by the FIB beam 51. The cross-section 52 is formed into the volume of the wafer 8 at approximately angle GF to the surface 55 of the wafer 8. The cross-section 52 is formed through an inspection volume 160 with dimensions of few μm, for example with a lateral extension of 5 μm to 10 μm in wafers with diameters of 200 mm or 300 mm. The damage to the wafer 8 is limited to the inspection volume 160. For example, with an inspection depth LZ about 10 μm, the damage volume in y-direction is typically limited to below 20 μm. The lateral extension can also be larger and reach up to few 10ths of micrometers. The cross-section surface 52 is scanned for example by SEM beam 44, which is in the example of FIG. 2 arranged at normal incidence to the wafer surface 55, and a high-resolution image can be generated.

For example, an image of the cross-section 52 comprises first cross-section image features, formed by intersections with high aspect ratio (HAR) structures or vias (for example first cross-section image features of HAR-structures 4.1, 4.2, and 4.3) and second cross-section image features formed by intersections with layers L.1 . . . L.M, which comprise for example SiO2, SiN-or Tungsten lines. Some of the lines are also called “word-lines”. The maximum number M of layers is typically more than 50, for example more than 100 or even more than 200. The layers are typically at constant depth and allow a depth determination below the wafer surface 55 within the inspection volume 160.

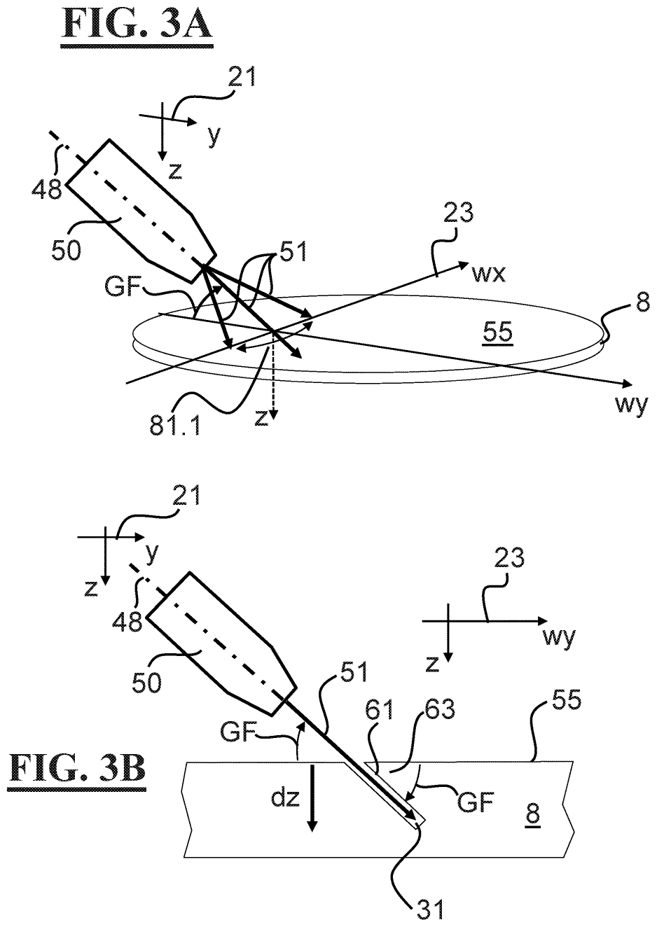

According to a second embodiment, a method of extracting samples, such as tiny samples, from full wafers is provided. A tiny sample has a small extension below 5 μm, below 3 μm or even less, for example below 1 μm in at least one dimension. According to the method, it is not required to break up a 200 mm or 300 mm wafer into small pieces. Instead, the method allows extracting tiny samples from full wafers. The method of extracting tiny samples from full wafers comprises forming cuts or intersections into the surface 55 of a wafer 55. A first example of forming a cut is illustrated in FIGS. 3A, 3B. FIG. 3A shows the FIB 50 with FIB axis 48. A wafer 8 is arranged on a stage (not shown) with a normal to the wafer surface 55 parallel to the z-axis (Note: the z-axis is pointing in the propagation direction of the imaging charged particle beam, not shown in FIGS. 3A, 3B). In system coordinates 21, the FIB axis 48 is arranged within the y-z-plane in the coordinate system 21 of a dual beam system 1, and the FIB-beam 51 is scanned in a first or x-direction perpendicular of normal to the y-z-plane. The y-z-plane is defined by comprising the FIB axis 48 and a normal to the wafer surface 55. For illustration, the scanning deflection 81.1 in the first direction is illustrated by an arrow with a highly exaggerated scanning range. Typically, the lateral scanning range is about 10 μm or even less. A wafer 8 is arranged in x-y-plane with wafer coordinate system 23 with wafer coordinates wx, wy parallel to x-and y-direction of the system coordinates 21. During scanning deflection 81 of FIB beam 51 in first or x-direction, an undercut 31 is formed within the wafer 8 and below surface 55, wherein the undercut 31 is formed at an angle GF with respect to the wafer surface 55. The undercut 31 at angle GF forms an undercut 31 below the wafer surface 55, forming a wafer volume 63 between the undercut 31 and the wafer surface 55. The undercut 31 is illustrated in FIG. 3B within wafer coordinates 23. The depth dz of the undercut 31 below the wafer surface 55 can be controlled by the milling time. The wafer volume 63 is separated by the undercut 31 and has a lower sidewall 61 at an angle GF to the wafer surface 55.

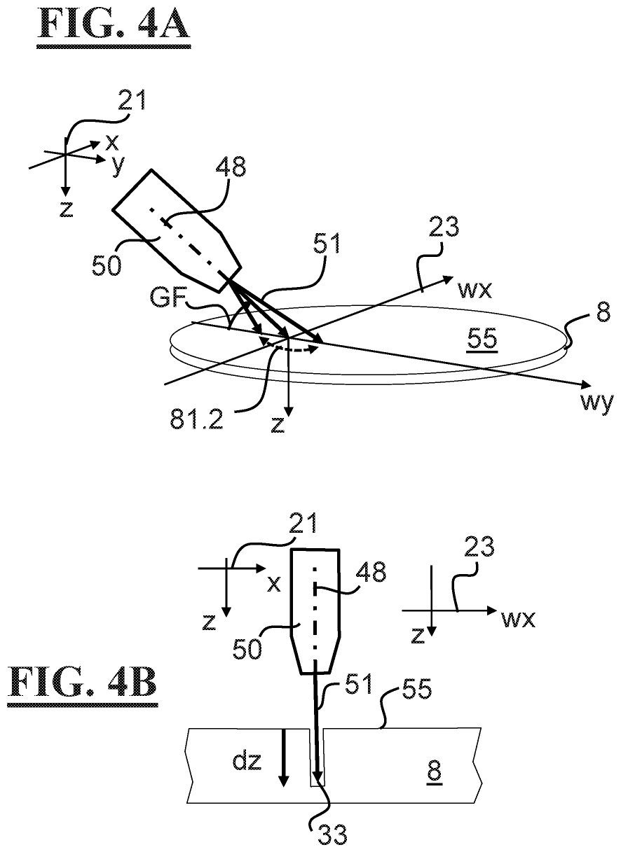

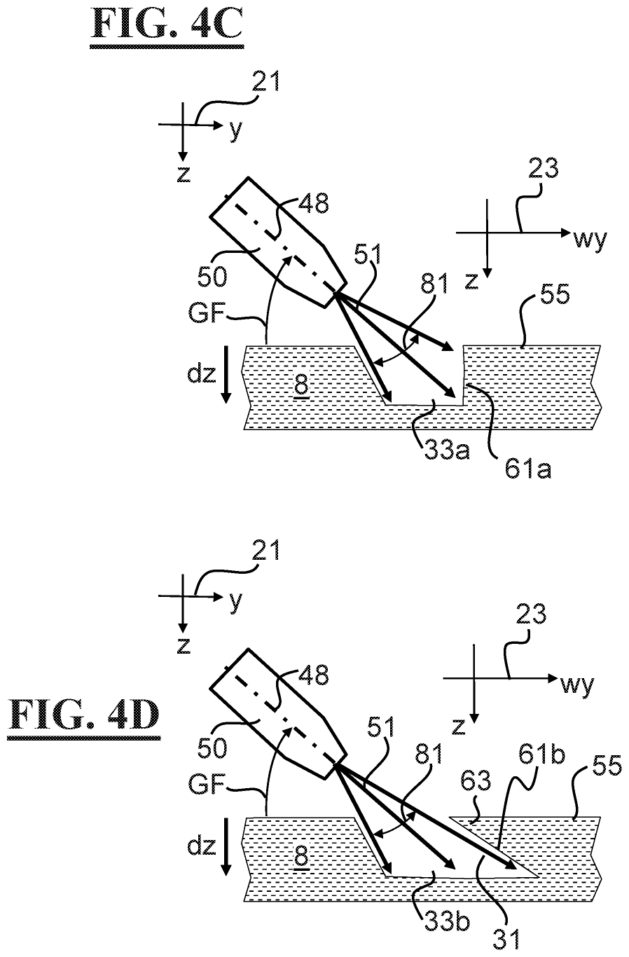

FIGS. 4A-4D illustrates another example of a milling operation for forming a normal cut 33 normal to the wafer surface 55. As illustrated in FIG. 4A, focused ion beam 51 is scanned in a second or y-direction, wherein the second scanning direction is within the y-z-plane and perpendicular to the first scanning direction illustrated in FIGS. 3A, 3B. FIG. 4B illustrates the normal cut 33 in wafer coordinates 23 in a projection in direction of the wy-coordinate. FIG. 4C illustrates a first example of a normal cut 33a in wafer coordinates 23 in a projection in direction of the wx-coordinate, with wy-axis parallel to the y-axis in system coordinates 21. Again, the scanning range of scanning deflection 81 is highly exaggerated. The depth dz of the normal cut 33a below the wafer surface 55 can be controlled by a locally variable milling time. Furthermore, a vertical wall 61a formed into the wafer 8 can be controlled by providing a locally variable milling time. In the example of normal cut 33a, a vertical wall 61a is formed normal to the wafer surface 55. In the example of FIG. 4D a normal cut 33b is illustrated which forms an undercut 31 in wy-direction below a volume segment 63 between the wafer surface 55 and the undercut 31. Here, the sidewall 61b is formed with an angle approximately given be angle GF.

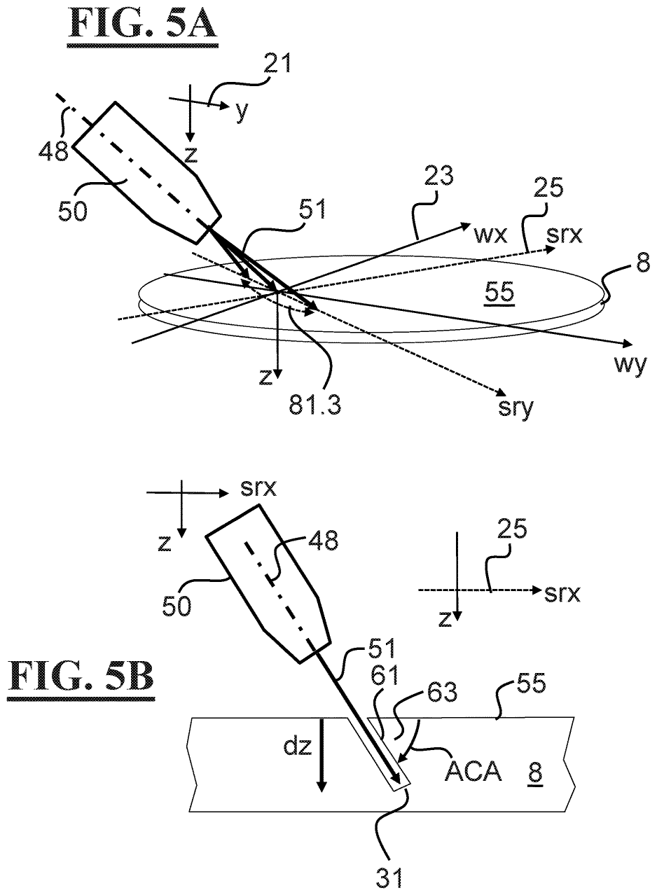

FIGS. 5A-5B illustrate another example of a milling operation for forming a undercut 31 at arbitrary cutting angle ACA. By scan rotation around the FIB axis 48, the focused ion beam 51 can be scanning deflected in a third direction at any angle to the first or second scanning direction, and in any plane comprising the FIB axis 48. In the example of FIG. 5A, scan rotation is performed such the focused ion beam 51 is scanned in a plane which intersects the wafer surface 55 along direction sry. Coordinate axes srx and sry therefore form a coordinate system according to the scan rotation with scanning deflection 81 along the third scanning direction along direction of coordinate sry. FIG. 5B illustrates a undercut 31 at an arbitrary angle ACA in a projection in direction of coordinate sry. The cutting angle ACA can be controlled by the scan rotation, i.e. by scanning deflecting the FIB 51 along the third scanning direction. The cutting angle ACA can be at any angle between angle GF and a normal to the wafer surface 55. Thereby, a wafer volume 63 with undercut 31 with steeper angle ACA compared to angle GF can be formed. The wafer volume 63 has an upper surface corresponding to the wafer surface 55 and one sidewall 61 with an angle ACA between angle GF and normal to the wafer surface.

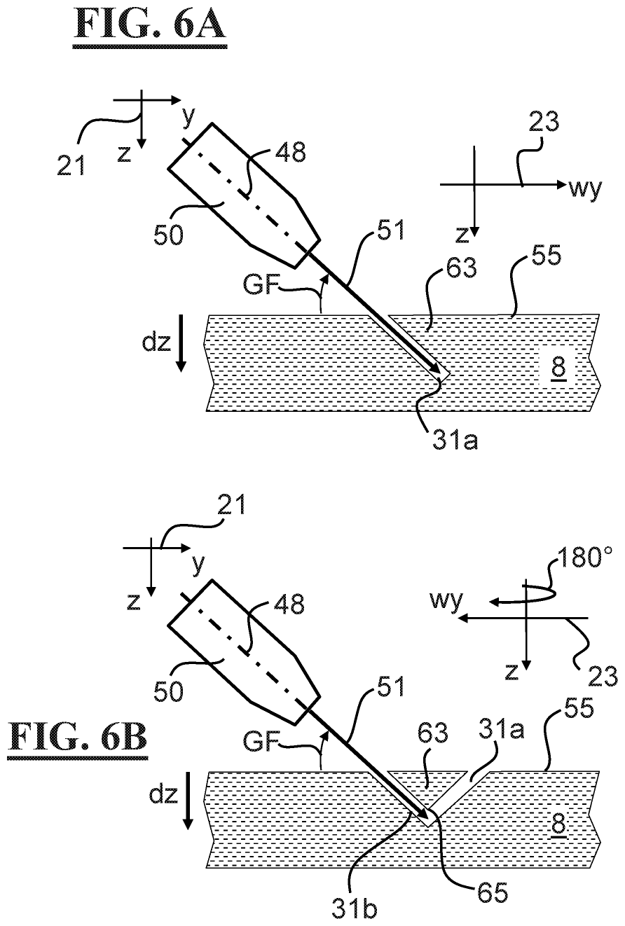

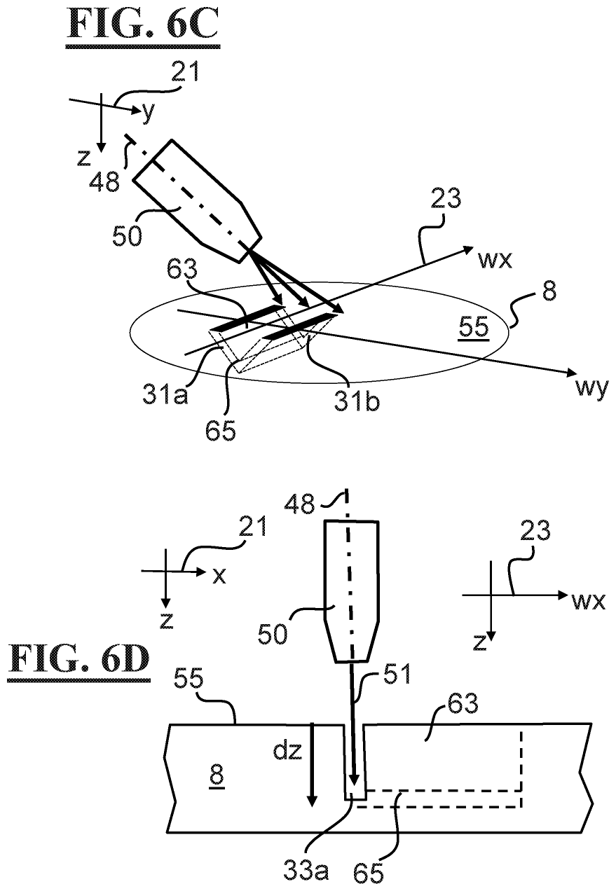

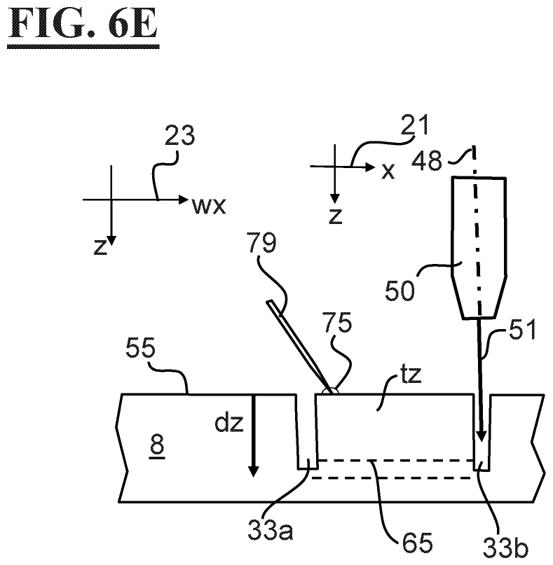

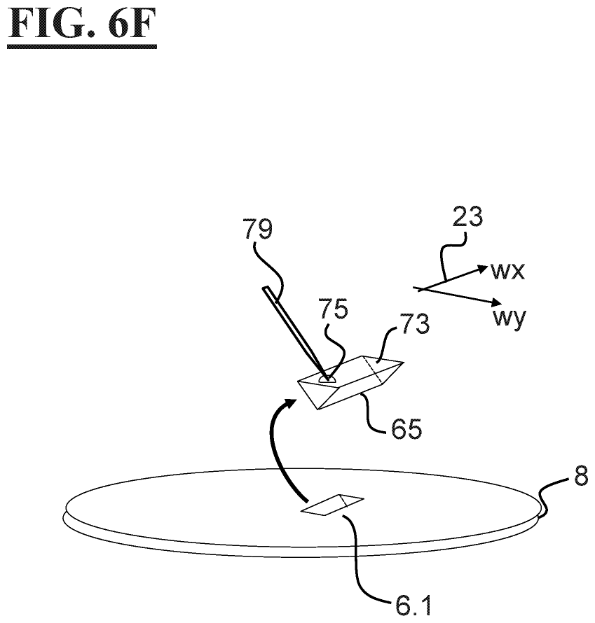

FIGS. 6A-6F illustrate a first example of the method of extracting samples, such as tiny samples, from full wafers. In a first step illustrated in FIG. 6A, a first undercut 31a is formed by scanning the focused ion beam 51 along the first scanning direction similar to a milling operation illustrated in FIGS. 3A, 3B. Thereby, a wafer volume 63 with an undercut is formed. In a second step, the wafer 8 is rotated by wafer stage 155 around z-axis by wafer rotation angle RA=180°, and optionally laterally displaced, and a second undercut 31b is formed by scanning the focused ion beam 51 along the first scanning direction similar to a milling operation illustrated in FIGS. 3A, 3B. The second milling is illustrated in FIG. 6B. The second milling step is formed such that the first undercut 31a and the second undercut 31b intersect each other at the lower end deep within the wafer at depth dz, thus forming a joint cutting intersection 65 deeply buried within the wafer 8, for example at a depth dz of 5 μm or more, for example 10 μm below the wafer surface 55. Both undercuts 31a and 31b form a wafer volume 63 between the two undercuts 31a, 31b and the wafer surface 55. In a third step illustrated in FIGS. 6C and 6D, a milling operation is performed by scanning deflection of the focused ion beam 51 along the second direction to mill a first normal cut 33a into the wafer 8 similar to the milling operation illustrated in FIGS. 4A-4D. The first normal cut 33a is formed adjacent to a first end of the wafer volume 63 with undercut. In another step illustrated in FIG. 6E, the micro-manipulator 79 is brought close to the wafer volume 63 with undercut and attached to it via charged particle beam assisted deposition, forming a positive substance joint 75 between the tip of micro-manipulator 79 and the wafer volume 63. In a fourth milling step, the remaining connection of the wafer volume 63 to the wafer 8 is disconnected by milling a second normal cut 33b at the second end of the wafer volume 63. Finally, the completely disconnected wafer volume 63 forms the tiny sample 73 and can be extracted by micro-manipulator 79 (see FIG. 6F) from the wafer 8 without breaking the wafer into pieces. According to the first example, the tiny sample 73 has an elongated shape with triangular cross-section according to the milling angles according to FIB angle GF. A thickness in a direction normal to the wafer surface 55 corresponds to the milling depth dz and can be up to several μm, for example up to 10 μm. The tiny sample 73 can be further treated by ion beam milling or polishing and a TEM lamella can be fabricated therefrom by known front-side or backside milling or polishing techniques.

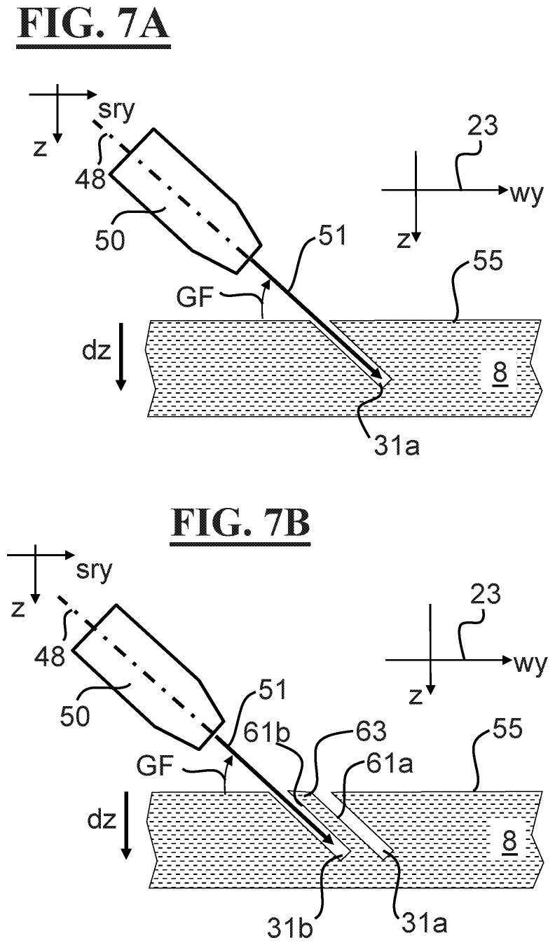

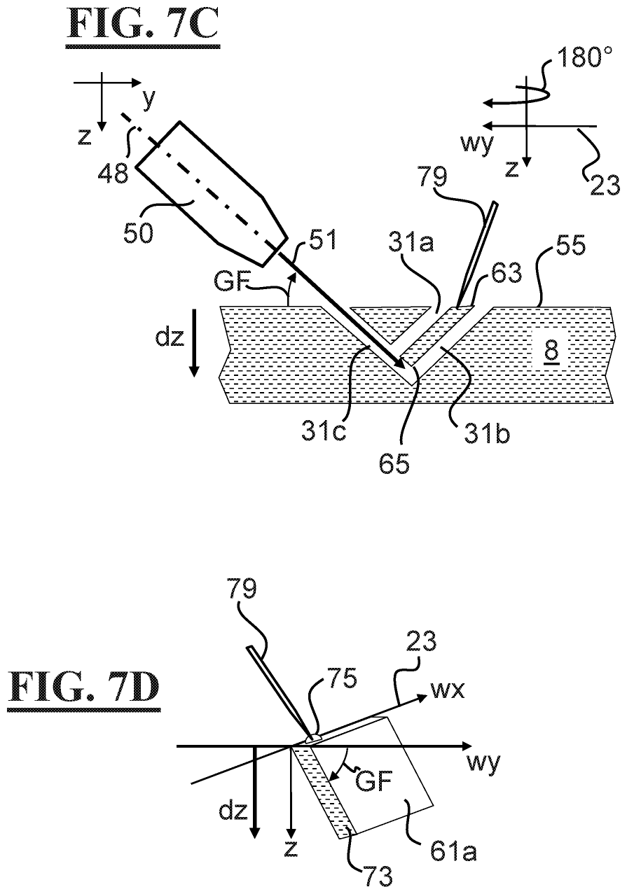

FIGS. 7A-7D illustrate a second example of the method of extracting tiny samples from full wafers. In a first step illustrated in FIG. 7A, a first undercut 31a is formed by scanning the focused ion beam 51 along the first scanning direction similar to the first example. In a second step, the scanning position is changed in y-direction, and a second undercut 31b is formed by scanning the focused ion beam 51 along the first scanning direction parallel to the first cut 31a and at the same or at least similar angle. The second milling is illustrated in FIG. 7B. The second milling step is formed such that the first cut 31a and the second cut 31b are at almost parallel to each other, thus forming a wafer volume 63 between the two undercuts 31a, 31b, and with parallel sidewalls 61a, 61b, both inclined at angle GF relative to the wafer surface 55. The distance between the two parallel cuts 31a and 31b can be controlled to very high precision, such that a thickness of the wafer volume 63 between the parallel sidewalls 61a, 61b is for example below 1 μm, for example 0.5 μm or even less. The wafer is rotated by wafer rotation angle RA=180°, and a third undercut 31c is formed by scanning the focused ion beam 51 along the first scanning direction such that a cutting intersection 65 between third undercut 31c, first undercut 31a and second undercut 31b is formed in a predetermined depth dz below the wafer surface 55. A micro-manipulator 79 is attached to the wafer volume 63 by forming a positive substance joint between the tip of micro-manipulator 79 and the wafer volume 63. In further milling steps, the remaining connection of the wafer volume 63 is disconnected by milling first and second normal cuts 33a and 33b by scanning the focused ion beam 51 along the second scanning direction. Finally, the completely disconnected wafer volume 63, forming the tiny sample 73 can be extracted by micro-manipulator 79. The tiny sample 73 according to the second example is illustrated in FIG. 7D and has a shape of a disk with parallel sidewalls 61a, 61b according to the milling angles according to FIB angle GF. The tiny sample 73 can be further treated by ion beam milling or polishing and a TEM lamella can be fabricated therefrom by known front-side or backside milling or polishing techniques.

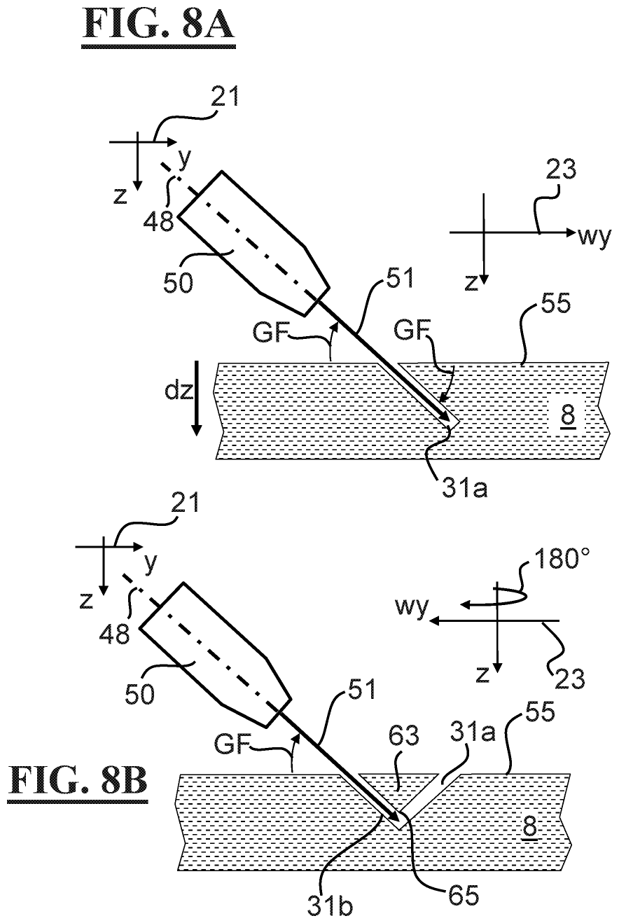

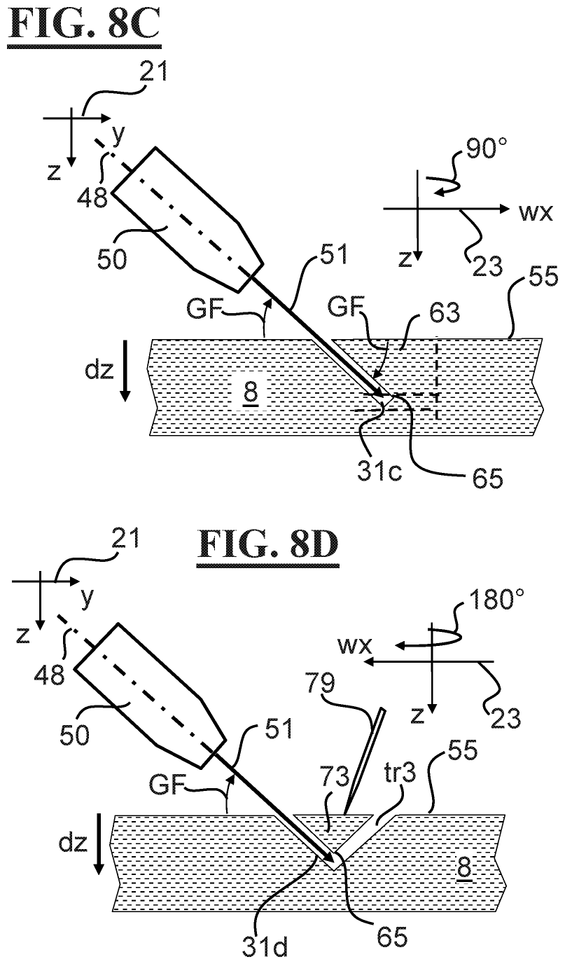

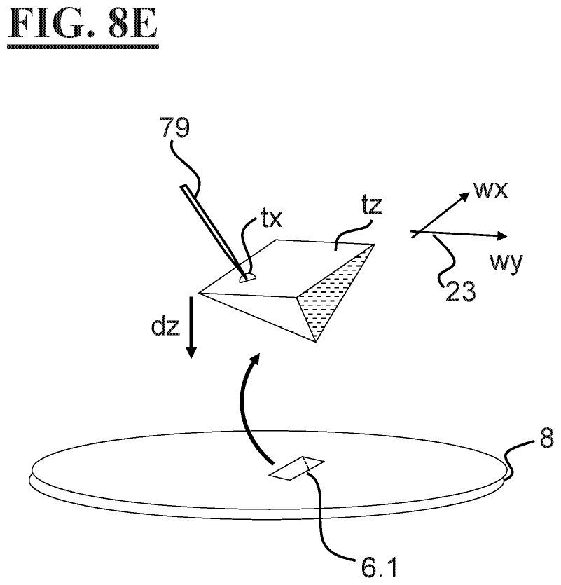

FIGS. 8A-8E illustrate a third example of the method of extracting tiny samples from full wafers. In a first step illustrated in FIG. 8A, a first undercut 31a is formed by scanning the focused ion beam 51 along the first scanning direction. In a second step, the wafer 8 is rotated by wafer rotation angle RA=180°, and a second undercut 31b is formed by scanning the focused ion beam 51 along the first scanning direction. The second milling is illustrated in FIG. 8B. In a third milling step, the wafer is rotated by wafer rotation angle RA=90°, and a third undercut 31c is formed by scanning the focused ion beam 51 along the first scanning direction such that a cutting intersection 65 between third undercut 31c, first undercut 31a and second undercut 31b is formed in a predetermined depth below the wafer surface 55. The wafer 8 is then rotated by wafer rotation angle RA=180° and a micro-manipulator 79 is attached to the wafer volume 63 by forming a positive substance joint between the tip of micro-manipulator 79 and the wafer volume 63. In fourth milling step, the remaining connection of the wafer volume 63 is disconnected by milling a fourth undercut 31d at angle GF by scanning the focused ion beam 51 along the first scanning direction. Milling position and depth is adjusted such that the fourth undercut 31d intersects with cutting intersection 65 at a predetermined depth dz below the wafer surface 55. The completely disconnected wafer volume 63 is forming the tiny sample 73 and can be extracted by micro-manipulator 79 from the wafer 8 without breaking the wafer 8 into pieces (FIG. 8E). The tiny sample 73 according to the third example is illustrated in FIG. 8E and has a shape of a pyramid with sidewalls according to the milling angles according to FIB angle GF. The tiny sample 73 can be further treated by ion beam milling or polishing and a TEM lamella can be fabricated therefrom by known front-side or backside milling or polishing techniques. In the third example, four cuts 31 a to 31 d are formed at 90° angle between adjacent cuts, and a tiny sample 73 with the shape of a pyramid is formed. The third example is however not limited to four undercuts 31a to 31d. For example, with a minimum of three undercuts at wafer rotation angles RA=120°, a tiny sample 73 with the shape of a tetrahedron is formed. Generally, with FIB-milling by scanning deflection of the FIB 51 in a first, second or third direction, at least three cuts are desirable to disconnect and extract a tiny sample 73 from a wafer.

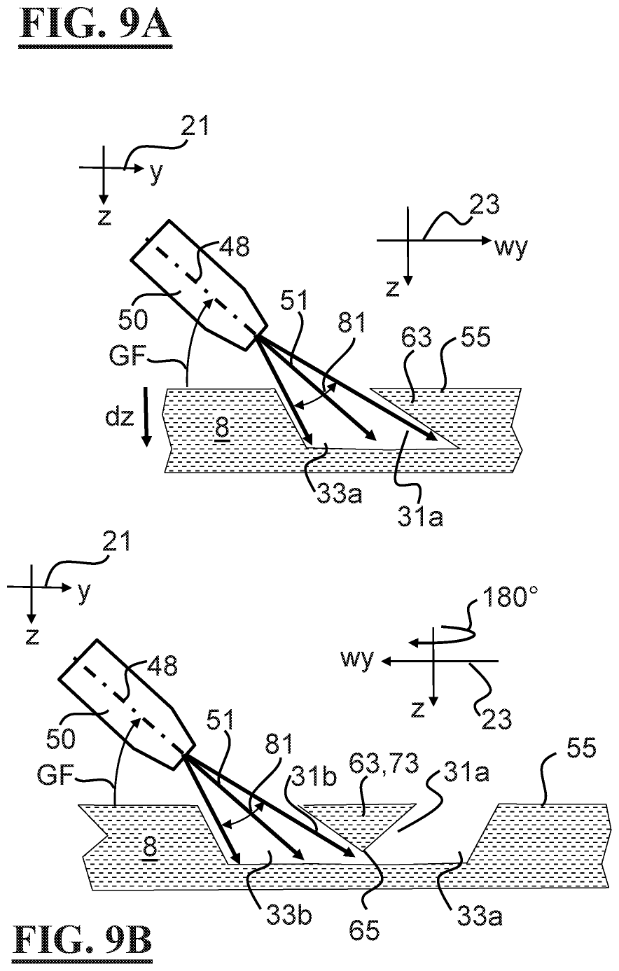

FIGS. 9A-9B illustrate a fourth example of the method of extracting tiny samples from full wafers. The fourth example is similar to the first example with the difference that the scanning deflection 81 is performed along the second scanning direction in the y-z-plane similar to the example illustrated in FIG. 4D. In a first step illustrated in FIG. 9A, a first normal cut 33a is formed. The milling time per y-coordinate is controlled such that an undercut 31a is formed below a wafer surface 63 between the wafer surface 55 and the undercut 31 a. The wafer is rotated by wafer rotation angle RA=180° and a second normal cut 33b is formed adjacent to the first cut 33a. The second milling is illustrated in FIG. 9B. The milling time per y-coordinate is controlled such that a second undercut 31b is formed below a wafer surface 63 between the wafer surface 55 and the second undercut 31b. The second milling step is formed such that the first undercut 31a and the second undercut 33b intersect each other and form a cutting intersection 65 at depth dz within the wafer 8, for example at a depth dz of 5 μm or more, for example 10 μm below the wafer surface 55. Both normal cuts 33a and 33b form undercuts 31a, 31b and a wafer volume 63 with undercut. In further steps similar to the first example, the wafer volume 63 is connected to micro-manipulator 76 and disconnected from the wafer 8 by two additional milling steps similar to the first example. Finally, the completely disconnected wafer volume 63 forms the tiny sample 73 and can be extracted by micro-manipulator 79 (not shown). According to the fourth example, the tiny sample 73 has a disk shape with triangular cross-section according to the milling angles according to FIB angle GF. A thickness of the disk can be very small, for example below 1 μm, below 0.5 μm or even less. The tiny sample 73 can be further treated by ion beam milling or polishing and a TEM lamella can be fabricated therefrom by known front-side or backside milling or polishing techniques. With the fourth example, a damage to the wafer 8 can be limited to a very small area. The advantage of the fourth example is that the wafer 8 has to be rotated only once by the wafer stage 155 and all milling steps are executed by scanning deflection of the FIB 51 in the second direction.

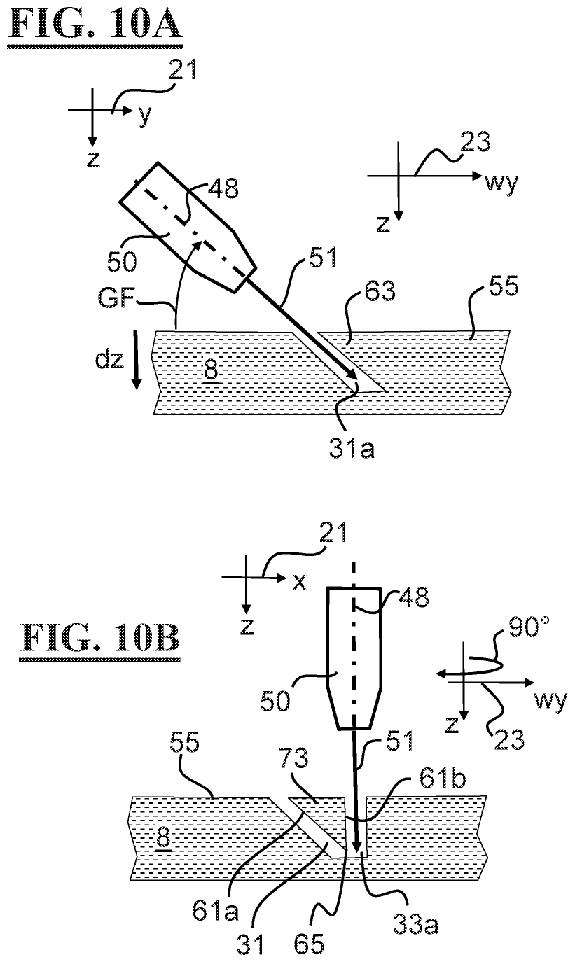

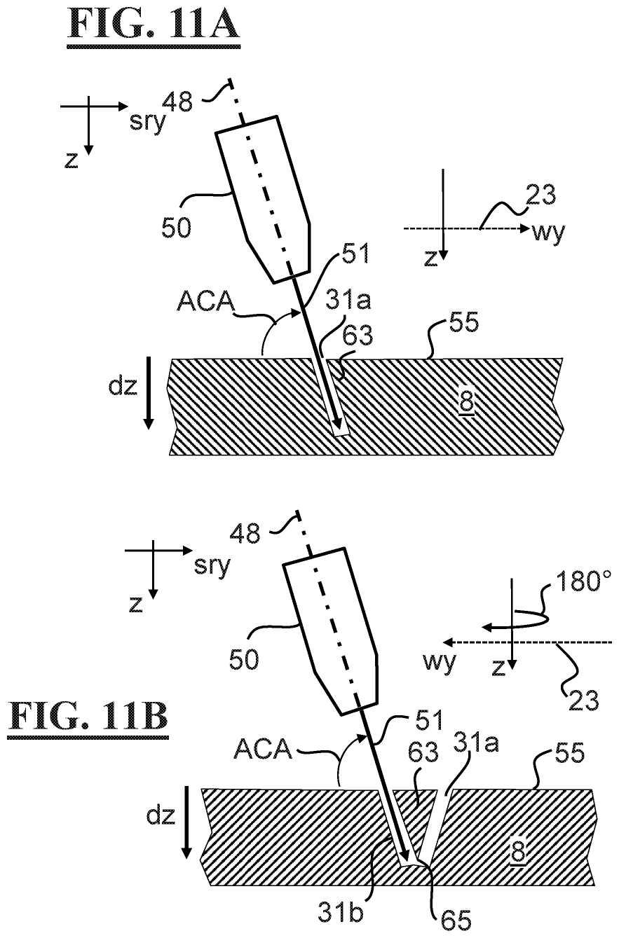

Forming a joint cutting intersection 65 at a depth dz is not limited to milling operations for forming at least two undercuts 31a, 31b. For example, a wafer volume 63 with an undercut 31 can also be formed by a single milling operation for forming a single undercut 31. FIGS. 10A, 10B illustrate a fifth example of the method of extracting tiny samples from full wafers with a single undercut 31. In a first step illustrated in FIG. 10A, an undercut 31 is formed at angle GF in a first milling step by scanning the focused ion beam 51 along the first scanning. In a second step, the wafer 8 is rotated by wafer rotation angle RA=90°, and a normal cut 33 a is formed by scanning the focused ion beam 51 along the second scanning direction similar to the method illustrated in FIG. 4B, such that the undercut 31 and the normal cut 33a form a cutting intersecting 65 deeply below the wafer surface 55. The second milling step is illustrated in FIG. 10B. Further steps according to the first example allow disconnection of the wafer volume 63 with undercut 31 and attachment to micro-manipulator similar to the description of the examples above. The tiny sample 73 according to the fifth example has an elongated shape of a triangular cross section with one sidewall 61a according to the milling angle GF and one sidewall 61b normal to the wafer surface 55. The tiny sample 73 can be further treated by ion beam milling or polishing and a TEM lamella can be fabricated therefrom by known front-side or backside milling or polishing techniques.

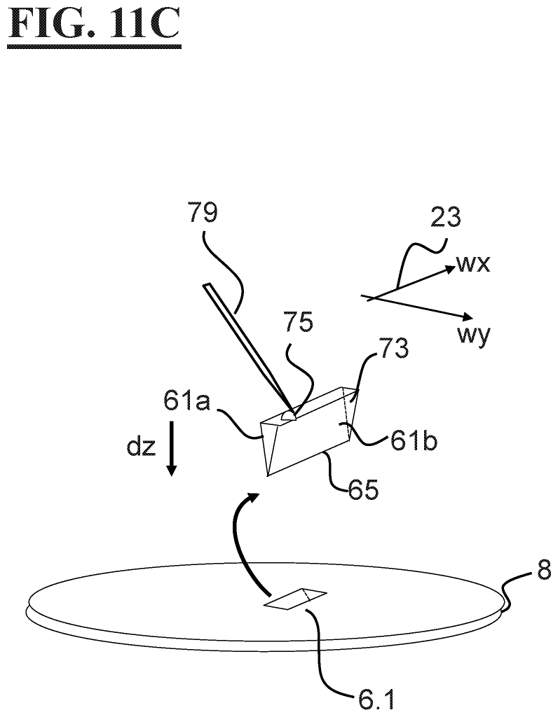

The first to fifth examples are illustrated by using scanning 81 deflection along the first or second scanning direction, and with cutting angles either given by the milling angle GF or normal to the wafer surface 55. The cutting angle is however not limited thereto. As illustrated at FIGS. 5A, 5B, scanning deflection can be executed along a third direction of scanning deflection and milling can be executed at any milling angle ACA between angle GF and 90°, i.e. normal to the wafer surface 55. FIGS. 11A-11C illustrates a sixth example similar to the first example, where a steep milling angle ACA is used instead of milling angle GF. In a first step illustrated in FIG. 11A, a first undercut 31a at angle ACA is formed by scanning deflection of FIB 51 along a third scanning direction, similar to a milling operation illustrated in FIGS. 5A, 5B. Thereby, a wafer volume 63 with an undercut 31a is formed. In a second step, the wafer 8 is rotated by wafer stage 155 around z-axis by wafer rotation angle RA=180°, and a second undercut 31b at angle ACA is formed is formed by scanning deflection of FIB 51 along a third scanning direction similar to a milling operation illustrated in FIGS. 5A, 5B. The second milling is illustrated in FIG. 11B. The second milling step is formed such that the first undercut 31a and the second undercut 31b intersect each other at the lower end deep within the wafer, thus forming a joint cutting intersection 65 deeply buried within the wafer 8, for example at a depth dz of 5 μm or more, for example 10 μm below the wafer surface 55. Both undercuts 31a and 31b form a wafer volume 63 below the wafer surface 55. Further steps similar to the first example are used to completely disconnect the wafer volume 63 from the wafer 8 and extract the wafer volume 63 by micro-manipulator 79, thus forming and extracting the tiny sample 73. According to the example, the tiny sample 73 has an elongated shape with triangular cross-section according to the milling angles ACA according to the scan rotation into the third scanning direction (see FIG. 11C). The tiny sample 73 can be further treated by ion beam milling or polishing and a TEM lamella can be fabricated therefrom by known front-side or backside milling or polishing techniques.

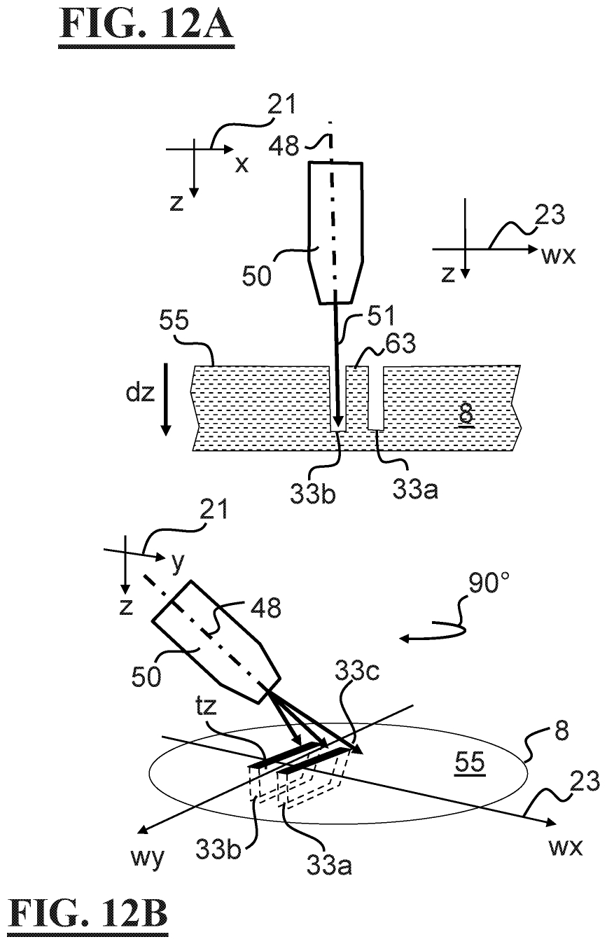

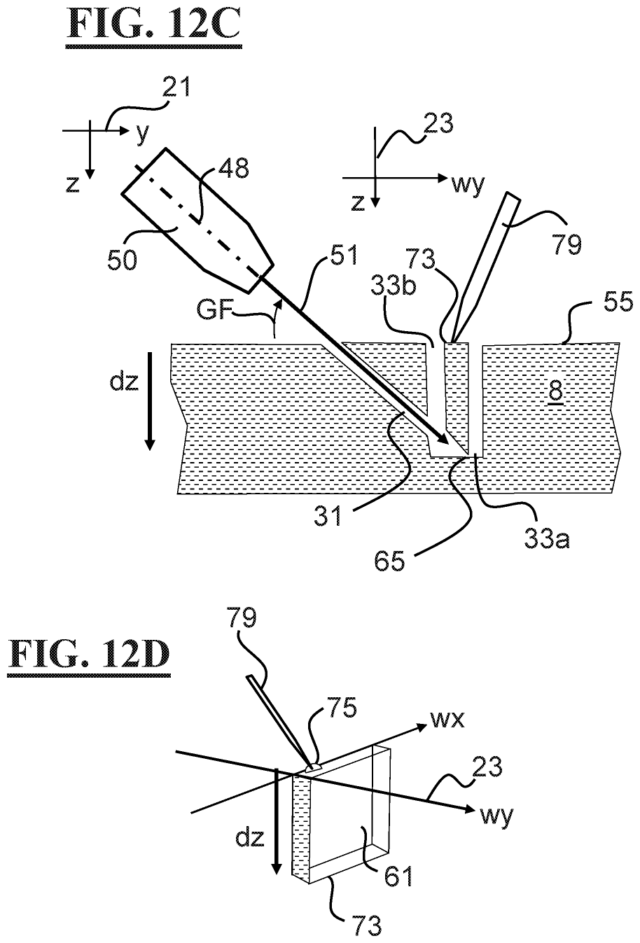

FIGS. 12A-12D illustrate a seventh example of the method of extracting tiny samples from full wafers. In a first and a second step illustrated in FIG. 12A, a first normal cut 33a and a second normal cut 33b are formed perpendicular to the wafer surface 55 by FIB milling with a second scanning direction illustrated in the example of FIGS. 4A-4D. The two normal cuts 33a and 33b are formed parallel to each other with a distance of below 1 μm, for example 0.5 μm or even less. Thereby, a wafer volume 63 is formed between the two normal cuts 33a, 33b, wherein in subsequent steps, the tiny sample 73 is formed from the wafer volume 63, which is still connected to the wafer 8. In a third step, the wafer 8 is rotated by wafer rotation angle RA=90° and a third normal cut 33c is milled at one end of the wafer volume 62 (see FIG. 12B). A second normal cut 33d is formed at the opposite end (not shown), such that the wafer volume 63 is only connected via the bottom to the wafer 8. To separate and extract the tine sample 73 from the wafer 8, first a micro-manipulator 79 is attached to the wafer volume 63, and a oblique cut 31 or undercut 31 is milled adjacent to the first and second normal cuts 33a and 33b by scanning deflection of FIB 51 at the first scanning direction. The distance and milling angle is selected such that the undercut 31 forms a cutting intersection 65 with the first normal cut 33a deeply below the wafer surface 55, for example at a depth dz of more than 2 μm, more than 5 μm or even more, for example 10 μm (see FIG. 12C). By forming the cutting intersection 65, the remaining connection between the wafer volume 63 and the wafer 8 is removed and the wafer volume 63, now forming the tiny sample 73, can be extracted with the micro-manipulator 79. The tiny sample 73 according to the seventh example is illustrated in FIG. 12D. The tiny sample 73 according to the seventh example is formed as a thin disk with sides normal to the wafer surface 55. The tiny sample 73 can be further treated by ion beam milling or polishing and a TEM lamella can be fabricated therefrom by known front-side or backside milling or polishing techniques.

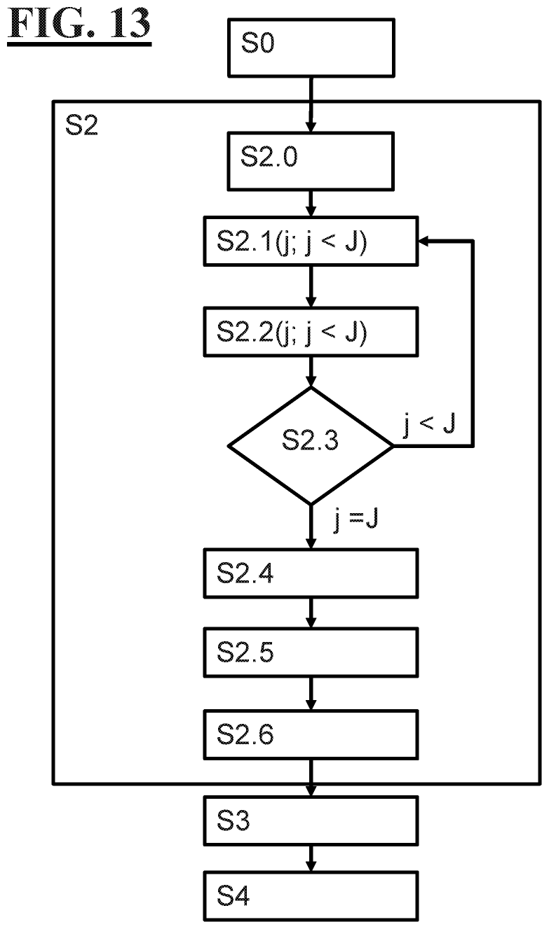

FIG. 13 illustrates an example of the method steps of the method of extracting tiny samples from full wafers. In a first step S0, an inspection site 6.1, 6.2 is selected and a wafer 8 is arranged by stage 155 such the selected inspection site 6.1, 6.2 is arranged at the intersecting point 43 of FIB axis 48 and the optical axis of imaging system 42. A shape, orientation and size of the tiny sample piece 73 to be formed is selected, for example shape and size of the tiny sample piece 73 is selected according to one of the first to seventh examples illustrated above. An orientation is selected for example according to CAD information or by a user input. The selection can be executed automatically according to predetermined selection stored for example in a memory of the wafer inspection system 1000. The selection can be performed or adjusted by user selection or user input via a user interface. For example, a shape, a length, a depth and an orientation of the tiny sample piece is selected by a user via a user interface.

In step S2, the tiny sample 73 is cut out and removed from the wafer 8. Therefore, in a step S2.0, a sequence of operations comprising milling operations, wafer movement, micro manipulator attachment is defined according to the selected shape, orientation and size of the tiny sample piece 73. For example, the sequence of milling operations comprises a wafer rotation by wafer rotation angle RA=90°, 120° or 180°, a wafer displacement in lateral direction, and a selection of a scan rotation angle of the focused ion beam 51 by selecting a scanning deflection along the first scanning direction, the second scanning direction normal to the first scanning direction, or a third scanning according to a scan rotation. According to the sequence of operations determined in step S2.0, at least J=three milling operations are determined for forming at least three cuts 31, 33, or 35 into the wafer 8. The step S2 of cutting and removing a tiny sample 73 comprises a sequence of at least three milling operations by focused ion beam 51.

The sequence comprises a step S2.1(j=1) of adjusting a lateral position and rotation angle RA of the wafer 8 for a milling operation via FIB 51. In a step S2.2(j=1), a scan rotation angle is adjusted and a milling operation with FIB 51 along scanning direction is executed. The scan rotation angle can be any angle between 0° (scanning in x-direction as illustrated in FIGS. 3A, 3B) and 90° (scanning in the y-z-plane, as illustrated in FIGS. 4A-4D). The milling time is controlled such that the desired depth dz selected in step S0 is reached. Milling operation can be monitored during milling with the charged particle beam imaging system 40.

In a step S2.3 the number of remaining milling operations according to the number of milling operations J is determined. If more than one milling operation is to be performed, steps S2.1(j) and S2.2(j) are repeated for the second or further cuts to be formed into the wafer surface 55. Steps S2.1(j) and S2.2(j) are repeated at least two times with j=1 and j=2. After performing J-1 cuts by focused ion beam 51, the wafer volume 63 corresponding to the tiny sample 73 to be extracted is only connected to the wafer 8 by a single side, which is to be disconnected by a final cut. If in step S2.3 it is determined that the number of cuts executed is j=J-1, such that the wafer volume 63 of the tiny sample 73 is only connected to the wafer 8 by a single side, Step S2.4 is executed and the wafer 8 is adjusted at the lateral position and rotation angle for the last remaining milling operation via FIB 51. In step S2.5, the wafer volume 63 to be extracted to form the tiny sample 73 is attached to a micro-manipulator 79. The attachment can be performed by charged-particle-beam assisted deposition of a material to bond micro-manipulator 79 to the wafer volume 63 as long as it is still connected to the wafer 8. Thereby, a positive substance joint 75 between micro-manipulator 79 and the tiny sample 73 is build. Finally, the final cut is executed in step S2.6 at the predetermined wafer rotation and scan rotation angle. The last connection of the wafer volume 63 to the bulk wafer 8 is disconnected by FIB milling and the tiny sample 73, attached to the micro-manipulator 79, can be extracted from the wafer 8.

At least one of the milling operations S2.2(j) or S2.6 comprises a focused ion beam milling forming an undercut 31 below a wafer surface 55 to form a wafer volume 63 between the undercut 31 and the surface of the wafer 8. An angle of at least one sidewall 61 of the wafer volume 63 is between the angle GF of the FIB optical axis 48 and a direction normal to the wafer surface 55, such that an undercut 31 is formed. At least two milling operations selected from the milling operations S2.2(j) or S2.6 are configured to form a joint cutting intersection 65 at a depth dz below the wafer surface 55.

In step S3, the tiny sample 73 is attached by a positive substance joint to a TEM lamella sample holder 93. Such process step is well known in the art. The tiny sample 73 is further processed via FIB milling in step S4, such that a thin TEM sample is formed from the tiny sample 73, for example a TEM sample with parallel sides is formed with a thickness of below 0.5 μm, for example 200 nm or less, for example 100 nm or even less. For example, a tiny sample 73 with triangular cross section according to the first, fifth or sixth example illustrated above in FIG. 6A-6F, 10A, 10B or 11A,11B is shaped into a TEM sample with parallel sidewalls by FIB milling. The TEM sample can further be polished by FIB polishing under a glancing angle of incidence of the focused ion beam 51. Such formation of TEM lamellas from extracted tiny samples 73 is well known in the art.

Various modifications of the method steps S0 to S4 of the method of extracting tiny samples from full wafers are possible. The method of extracting tiny samples 73 from a full wafer 8 comprises at least one focused ion beam milling step S2.2(j) or S2.6 for forming an undercut 31 below a wafer surface 55 of a wafer volume 63 to be extracted. The method of extracting tiny samples 73 from a full wafer 8 comprises at least one focused ion beam milling step S2.2(j) or S2.6 for forming an undercut 31 at an angle between angle GF between the FIB optical axis 48 and the wafer surface 55 and a normal to the wafer surface 55, such that a wafer volume 63 with an undercut 31 is formed between the wafer surface 55 and a sidewall 61 formed by the focused ion beam milling step S2.2(j), S2.6. In order to form a wafer volume 63 with an undercut, the milling angle ACA between the wafer surface 55 and a sidewall 61 can deviate from a normal to the wafer surface 55 by at least 5°, for example 10° or more. Thereby, a wafer volume 63 with an undercut is formed of sufficient depth dz and thickness for forming a TEM lamella thereof. Forming the wafer volume 63 with undercut involves at least one rotation of the wafer 8 between at least two subsequent FIB-milling steps S2.2(j with j=1 . . . J-1) and S2.6 by wafer stage 155 around the z-axis (normal to the wafer support surface 15). The at least one wafer rotation angle RA is for example 90°, 180° or 120°. In an example, the method forming the wafer volume 63 with undercut comprises at least one first milling step with a scanning deflection in a first or x-direction and at least one second milling step with a scanning deflection in a second scanning direction within the y-z-plane and normal to the first scanning direction. In an example, the method forming the wafer volume 63 with undercut further comprises at least one milling step at a scan rotation angle in a third scanning direction deviation from a scanning deflection in first or second scanning direction.

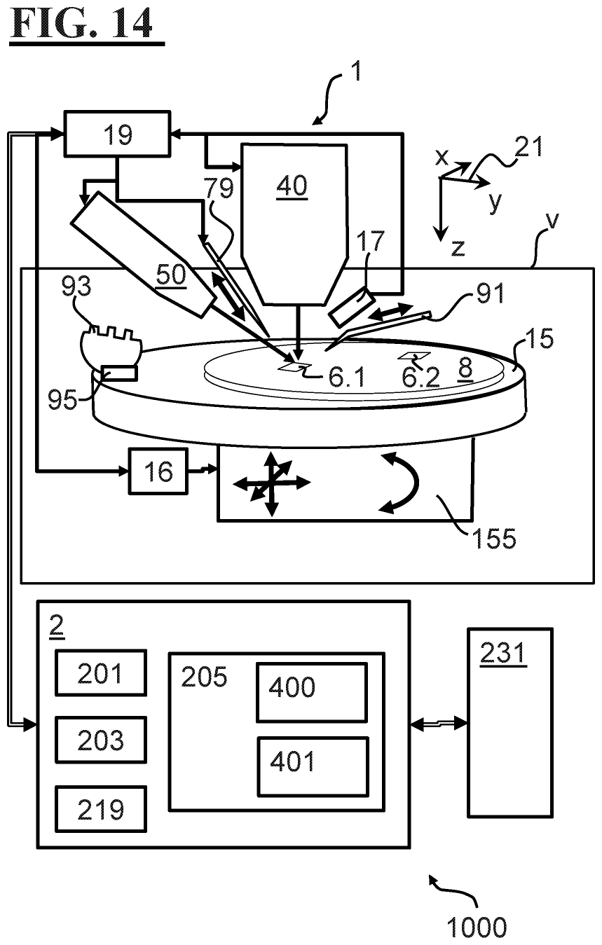

FIG. 14 illustrates further details of an example of a wafer inspection system 1000 according to the first embodiment. The wafer inspection system is configured for executing the method according to the second embodiment. The wafer inspection system 1000 comprises a dual beam system 1. A dual beam system is illustrated in FIG. 1 with more detail and reference is made to the description of FIG. 1. Certain features of a dual beam system 1 are a first charged particle or FIB column 50 for milling and a second, charged particle beam imaging system 40 for high-resolution imaging of cross section surfaces. A dual beam system 1 comprises at least one detector 17 for detecting secondary particles, which can be electrons or photons. A dual beam system 1 further comprises a wafer support table 15 configured for holding during use a wafer 8. The wafer support table 15 is connected to a stage 155 and is position controlled by a stage control unit 16, which is connected to the control unit 19 of the dual beam system 1. The support table 15 further comprises a sample holder bay 95 for holding common TEM Lamella sample holders 93. The stage is at least a five-axis stage capable of lateral movement and rotation in x-y-plane of the coordinate system of FIG. 14. The control unit 19 is configured with memory and logic to control operation of the dual beam system 1.

The wafer inspection system 1000 further comprises an operation control unit 2. The operation control unit 2 comprises at least one processing engine 201, which can be formed by multiple parallel processors including GPU processors and a common, unified memory. The operation control unit 2 further comprises an SSD memory and disk memory or storage 203 for storing of images. The operation control unit 2 further comprises a user interface 205, comprising the user interface display 400 and user command devices 401, configured for receiving input from a user. The operation control unit 2 further comprises a memory or storage 219 for storing process information of the method of sample extraction of a tiny sample according to the second embodiment and for storing software instructions, which can be executed by the processing engine 201. The software instructions comprise software for performing, when executed, a method according to the second embodiment.

The operation control unit 2 is further connected to an interface unit 231, which is configured to receive further commands or data, for example CAD data, a list of inspection sites 6.1, 6.2 . . . from external devices or a network. The interface unit 231 is further configured to exchange information, for example receive instructions from external devices or provide measurement results to external devices.

The inspection system 1000 is configured to receive user information, for example comprising CAD information of the semiconductor object of interest and the selection of an inspection site. The inspection system 1000 can be configured to combine the user information with process information of the sample extraction process according to the second embodiment. The processing engine 201 is further configured to execute the method steps S0 to S4 of the method described above. The processing engine 201 is thereby configured to display information via the user display 400 and to receive user input via user interface 401.

The disclosure is not limited to the examples and embodiments and can be implemented by those skilled in the art by various combinations or modifications.

### A LIST OF REFERENCE NUMBERS IS PROVIDED

1 Dual Beam system
2 Operation Control Unit
4 first cross section image features
6 measurement or inspection sites
8 wafer
15 wafer support table
16 stage control unit
17 Secondary or backscattered electron detector
19 Control Unit
21 system coordinates
23 wafer coordinates
25 scan rotation coordinates
31 cut at oblique angle
33 cut at normal angle
35 cut at arbitrary angle
40 charged particle beam (CPB) imaging system
42 Optical Axis of imaging system
43 Intersection point
44 Imaging charged particle beam
48 Fib Optical Axis
50 FIB column
51 focused ion beam
52 cross section surface
53 cross section surface
55 wafer top surface
61 sidewall
63 wafer volume
65 cutting intersection
73 tiny sample
75 positive substance joint
79 micro-manipulator
81 scanning deflection
91 gas injection system
93 TEM lamella sample holder
95 sample holder bay
101 objective lens with axial gap
155 wafer stage
157 tilt angle
160 inspection volume
201 processing engine
203 memory
205 User interface
219 memory
231 Interface unit
400 user interface display
401 user command devices
1000 Wafer inspection system

1. A method of extracting a tiny sample (73) corresponding to a wafer volume (63) from a wafer (8), comprising:
arranging an inspection site (6, 6.1) on a surface (55) of the wafer (8) at an intersection point (43) of an imaging charged particle beam (44) and a focused ion beam (51), the focused ion beam (51) arranged under an angle GF to the surface (25) of the wafer (8) with an angle GF between 20°<GF<60°,-performing a sequence of J milling operations for forming at least J>=3 cuts (31,33) into the surface (55) of the wafer (8),—rotating, between at least two milling operations selected from the sequence of J milling operations, the wafer (8) by a wafer rotation angle RA by a wafer stage (155) around an axis normal to the wafer surface (25),—before executing a final milling operation selected from the sequence of J milling operations, attaching a micro-manipulator (79) to the surface (25) of the wafer (8),-wherein the sequence of J milling operations comprises a final milling operation with the focused ion beam (51) for forming a final cut (31,33) into the wafer surface (25), thereby disconnecting a wafer volume (63) from the wafer (8).

2.-22. (canceled)
